(19) United States
(12) Patent Application Publication
(10) Pub. No.: US 2021/0391633 A1
(43) Pub. Date: Dec. 16, 2021

(54) INTEGRATED CIRCULATOR SYSTEM

(71) Applicants: Matthew A. Laurent, Redondo Beach, CA (US); Dino Ferizovic, Torrance, CA (US); Benjamin Poust, Hawthorne, CA (US); Kevin A. Matsui, Torrance, CA (US)

(72) Inventors: Matthew A. Laurent, Redondo Beach, CA (US); Dino Ferizovic, Torrance, CA (US); Benjamin Poust, Hawthorne, CA (US); Kevin A. Matsui, Torrance, CA (US)

(73) Assignee: NORTHROP GRUMMAN SYSTEMS CORPORATION, FALLS CHURCH, VA (US)

(21) Appl. No.: 17/320,527

(22) Filed: May 14, 2021

Related U.S. Application Data
(60) Provisional application No. 63/038,572, filed on Jun. 12, 2020.

(51) Int. Cl. H01P 1/387; H01P 1/36; H03H 7/38

(52) U.S. Cl. CPC H01P 1/387; H03H 7/38; H01P 1/36

(57) ABSTRACT

One example includes an integrated circulator system comprising a junction. The junction includes a first port, a second port, and a third port. The junction also includes a substrate material layer on which the first, second, and third ports are provided. The junction also includes a magnetic material layer coupled to the substrate layer. The junction further includes a resonator coupled to the first, second, and third ports to provide signal transmission from the first port to the second port and from the second port to the third port based on a magnetic field provided by the magnetic material layer.

### RELATED APPLICATIONS

The present invention claims priority from U.S. Provisional Patent Application No. 63/038572, entitled “INTEGRATED CIRCULATOR SYSTEM”, filed 12 Jun. 2020, which is incorporated herein by reference in its entirety.

### TECHNICAL FIELD

The present disclosure relates generally to electronic circuits, and specifically to an integrated circulator system.

### BACKGROUND

Circuit components that direct signals, particularly high frequency signals, has been an increasingly important feature for communications and computer systems. One such circuit component is a circulator that is configured to direct signals that are provided at separate ports to different ports of the circulator device in a non-reciprocal manner. As an example, circulators can be implemented to route signals to different portions of a circuit. As another example, circulators can be formed as isolators in which one of the ports provides signal termination. As a result, radio frequency (RF) signals that are input to a first port can be output from a second port, while spurious RF signals that are provided at the second port can be provided to the third port for termination. For example, such isolator devices can protect circuits upstream from the isolator device to ensure that solid state components are not biased outside of the limits of intended safe device operation.

### SUMMARY

One example includes an integrated circulator system comprising a junction. The junction includes a first port, a second port, and a third port. The junction also includes a substrate material layer on which the first, second, and third ports are provided. The junction also includes a magnetic material layer coupled to the substrate layer. The junction further includes a resonator coupled to the first, second, and third ports to provide signal transmission from the first port to the second port and from the second port to the third port based on a magnetic field provided by the magnetic material layer.

Another example includes a method of fabricating an integrated circulator system. The method includes selectively applying a first metal coating to a portion of a first surface of a substrate layer. The first metal coating corresponds to signal ports associated with the integrated circulator system. The method also includes selectively applying a second metal coating to a portion of a first surface of a magnetic material layer. The second metal coating corresponds to the signal ports associated with the integrated circulator system. The method also includes aligning the substrate layer and the magnetic material layer via the opposing first surfaces of each of the magnetic material layer and the substrate layer to form an interconnect layer that provides electrical connectivity between the first and second metal coatings. The method further includes applying a resonator to a second surface of the magnetic material layer opposite the first surface, and providing electrical connectivity between the resonator and the first and second metal coatings.

Another example includes an integrated circuit (IC) comprising an integrated circulator system. The integrated circulator system includes a junction. The junction includes a first port, a second port, and a third port. The junction also includes a substrate material layer on which the first, second, and third ports are provided. The junction also includes a magnetic material layer coupled to the substrate layer. The junction further includes a resonator coupled to the first, second, and third ports to provide signal transmission from the first port to the second port and from the second port to the third port based on a magnetic field provided by the magnetic material layer. The integrated circulator system also includes a first impedance-matching network that is unitary with the first port, the first impedance-matching network being coupled to a first microstrip transmission line configured to propagate an RF signal to the integrated circulator system. The integrated circulator system further includes a second impedance-matching network that is unitary with the second port, the second impedance-matching network being coupled to a second microstrip transmission line configured to propagate the RF signal from the integrated circulator system.

### BRIEF DESCRIPTION OF THE DRAWINGS

FIG. 1 illustrates an example of an integrated circulator system.

FIG. 2 illustrates an example of a junction of an integrated circulator system.

FIG. 3 illustrates an example diagram of an integrated isolator system.

FIG. 4 illustrates an example of an integrated circuit.

FIG. 5 illustrates an example of an isolator.

FIG. 6 illustrates an example of a method for fabricating an integrated circulator system.

### DETAILED DESCRIPTION

The present disclosure relates generally to electronic circuits, and specifically to an integrated circulator system. The integrated circulator system can be implemented in any of a variety of radio frequency (RF) signal communication systems. For example, the integrated circulator system can be implemented as a signal isolator to provide unidirectional propagation of an RF signal on a transmission line based on routing signals in a non-reciprocal manner. The integrated circulator system can include a junction and a set of impedance matching networks associated with each of at least two signal ports associated with the junction. The impedance matching networks can thus provide a transitional impedance matching between the associated circulator and transmission lines on which the RF signals propagate (e.g., input and output signals). As another example, the integrated circulator system can include a termination resistor instead of an impedance matching network for one of the ports of the junction, such as to provide an isolator function to sink spurious input signals that are provided at the output port.

As an example, the integrated circulator system can be implemented in any of a variety of circuit systems, and can be fabricated in an integrated circuit fabrication process. For example, the integrated circulator system, any circuits that are coupled to the respective impedance-matching networks and any microstrip transmission lines interconnecting therebetween can all be fabricated on a single integrated circuit in an integrated fabrication process. Therefore, the impedance matching networks can be coupled to respective microstrip transmission lines on a printed circuit board (PCB) or integrated circuit (IC) chip. For example, the impedance matching networks can be fabricated on a substrate, such as the same substrate on which the integrated circulator system is fabricated. As an example, a first microstrip transmission line can provide an RF signal to a first port of the junction via the first impedance-matching network. The circulator system 100 can thus route the RF signal to a second port to output the RF signal to the second impedance-matching network to propagate the RF signal via another microstrip transmission line. An RF signal that is provided to the second port can thus be provided to a third port that is coupled to the third impedance-matching network via the circulator system.

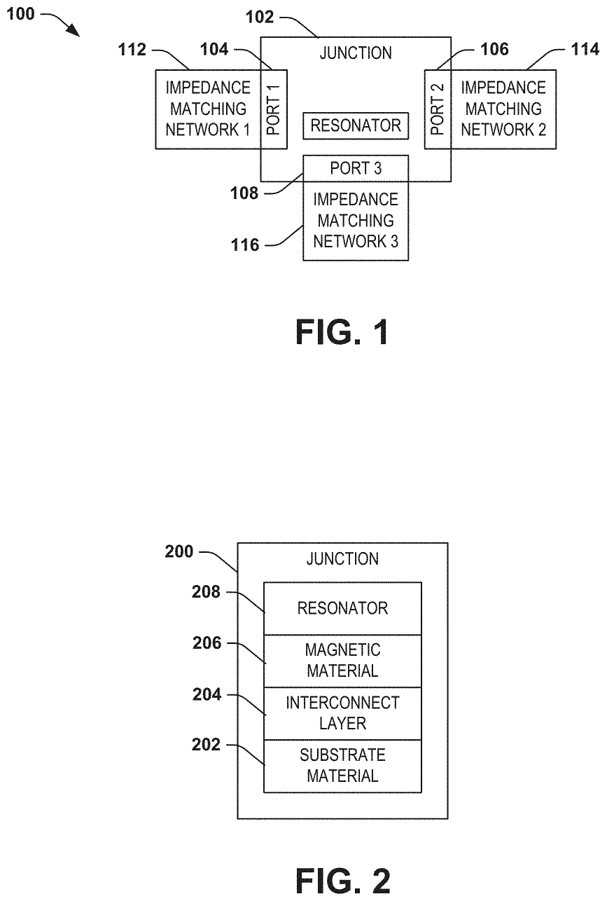

FIG. 1 illustrates an example of an integrated circulator system 100. The integrated circulator system 100 can be implemented in any of a variety of RF signal communication systems. As described herein, the integrated circulator system 100 can be fabricated in an integrated circuit fabrication process.

The integrated circulator system 100 includes a junction 102 that includes a first port 104, a second port 106, and a third port 108. As described herein, RF signals that are provided to a given one of the ports 104, 106, and 108 is provided to a next port around the junction 102. Therefore, an RF signal provided to the first port 104 is provided to the second port 106 by the junction 102, an RF signal provided to the second port 106 is provided to the third port 108 by the junction 102, and an RF signal provided to the third port 108 is provided to the first port 104 by the junction 102. In the example of FIG. 1, the junction includes a resonator 110 that is configured to implement the RF signal transfer between the ports 104, 106, and 108, as described in greater detail herein.

In the example of FIG. 1, the integrated circulator system 100 includes a first impedance-matching network 112 coupled to the first port 104, a second impedance-matching network 114 coupled to the second port 106, and a third impedance-matching network 116 coupled to the third port 108. As an example, the integrated circulator system 100, any circuits that are coupled to the respective impedance-matching networks 112, 114, and 116, and any microstrip transmission lines interconnecting therebetween can all be fabricated on a single integrated circuit in an integrated fabrication process, as described herein. The impedance matching networks 112, 114, and 116 can thus provide impedance matching between the junction 102 and the microstrip transmission lines that are coupled thereto.

For example, the first impedance-matching network 112 can be coupled to a microstrip transmission line (not shown) that provides an RF signal to the first port 104 of the junction 102 via the first impedance-matching network 112. The circulator system 100 can route the RF signal to the second port 106 to output the RF signal to the second impedance-matching network 114 to be output on another microstrip transmission line (not shown). Any RF signals that are provided to the second port 106 can thus be provided to the third port 108 coupled to the third impedance-matching network 116. As another example, as described in greater detail herein, the third impedance matching network 116 can instead be arranged as a terminating resistor, such as based on the integrated circulator system 100 being configured as a signal isolator.

FIG. 2 illustrates an example of a junction 200 of an integrated circulator system (e.g., the integrated circulator system 100). The junction 200 can correspond to the junction 102 of the integrated circulator system 100. Therefore, reference is to be made to the example of FIG. 1 in the following description of the example of FIG. 2.

The junction 200 includes a substrate layer 202, an interconnect layer 204, a magnetic material layer 206, and a resonator 208. The substrate layer 202 can be any of a variety of substrate materials (e.g., GaAs or any of a variety of semiconductor or dielectric materials) on which transmission lines (e.g., microstrip transmission lines) can be patterned to conduct signals (e.g., RF signals). The magnetic material layer 206 can overlay the substrate layer 202, such that the interconnect layer 204 can interconnect the substrate layer 202 and the magnetic material layer 206. The resonator 208 can be disposed on an opposite surface of the magnetic material layer 206 relative to the interconnect layer 204. As an example, the magnetic material layer 206 can be formed as a ferrite material slab to provide a direct current (DC) magnetic field that facilitates the non-reciprocal routing of signals through the resonator 208 between the respective ports of the circulator system (e.g., the ports 104, 106, and 108 of the integrated circulator system 100). As an example, the magnetic material layer 206 can be a self-biased ferrite material, such as a hexaferrite material (e.g., barium or strontium), or can be a ferrite material that provides a DC bias in response to an external magnetic field generator (not shown). The order and arrangement of the layers are not intended to be limited to as demonstrated in the example of FIG. 2, but can instead be arranged in any of a variety of ways.

As an example, the resonator 208 can be configured as a contiguous piece of metal electrically that is connected to the first, second, and third ports 104, 106, and 108, such that the first, second, and third ports 104, 106, and 108 can be effectively short-circuited with respect to each other. As another example, traces can extend from the resonator 208 and can contact electrical vias. The electrical vias can contact a trace on the underside of the magnetic material layer 206, and the interconnect layer 204 can extend the conductive connection to the surface of the substrate material 202. As an example, the first, second, and third ports 104, 106, and 108 can be probed on the substrate material 202.

As an example, the interconnect layer 204 can be arranged as a metal coating that is selectively deposited on each of opposing surfaces of the substrate layer 202 and the magnetic material layer 206 via a selective metallization deposition process (e.g., via metal coating or lithography processes). The interconnect layer 204 can also include a plurality of interconnect conductors that provide electrical connectivity between the metal coatings on the substrate layer 202 and the magnetic material layer 206. For example, the interconnect conductors can be configured as any of a variety of conductive materials (e.g., solder balls or soft conductive materials that can fuse with the metal coatings) to provide a low-loss electrical connection between the metal coatings on the surface of the substrate layer 202 and the opposing surface of the magnetic material layer 206. Therefore, during the fabrication process, the magnetic material layer 206 can be precision aligned with the substrate layer 202 to provide electrical connection between the signal ports 104, 106, and 108 of the circulator system 100 and between ground planes of the circulator system 100.

As an example, the substrate layer 202 can extend beyond the edges of the overlying layers (e.g., the interconnect layer 204, the magnetic material layer 206, and the resonator 208). Therefore, as an example, the first impedance-matching network 112, the second impedance-matching network 114, and the third impedance-matching network 116 can be fabricated on the substrate layer 202, such as beyond the edges of the overlying layers. For example, the signal ports 104, 106, and 108 can be fabricated from the metal coatings on the substrate layer 202 and/or the metal coatings on the magnetic material layer 206. As another example, the portions of the metal coatings of the substrate layer 202 and the magnetic material layer 206 that correspond to the signal ports 104, 106, and 108 can be coupled to respective electrical vias that extend through the magnetic material layer 206 to provide electrical connectivity to the resonator 208 on the opposite surface of the magnetic material layer 206.

Therefore, based on the arrangement of the junction 200, an RF signal that is provided through the first impedance-matching network 112 to the first port 104 of the junction 102, at the metal coating on the surface of the substrate layer 202 associated with the first port 104, can be electrical connected to the corresponding metal coating on the surface of the magnetic material layer 206 associated with the first port 104 via one or more interconnect conductors of the interconnect layer 204. The RF signal can thus be routed through a conductive via through the magnetic material layer 206 to the resonator 208 to be routed through another conductive via through the magnetic material layer 206 to the metal coating on the surface of the magnetic material layer 206 associated with the second port 106. The RF signal can thus propagate through the interconnect conductor to the metal coating on the surface of the substrate layer 202 associated with the second port 106 and can be output from the junction 200 to the second impedance-matching network 114. Signals provided to the second and third ports 106 and 108 can likewise propagate through the circulator system 100 in a similar manner.

As described herein, the junction 200 can be fabricated as part of the integrated circulator system 100 in an integrated fabrication process, along with associated circuits and interconnects therebetween. Therefore, the integrated circulator system 100 can be implemented in a much more compact manner than typical circulator and/or isolator circuits that are implemented as discrete components. For example, because typical circulators and isolators are implemented as discrete components, signal losses can occur based on soldered and/or mechanical conductive connections between the discrete devices, and the discrete devices can occupy significantly greater physical volume. Additionally, based on the arrangement of the interconnect layer 204 as including metal coatings on the respective surfaces of the substrate layer 202 and the magnetic material layer 206, the functionality of the integrated circulator system 100 can be split between the substrate layer 202 and the magnetic material layer 206.

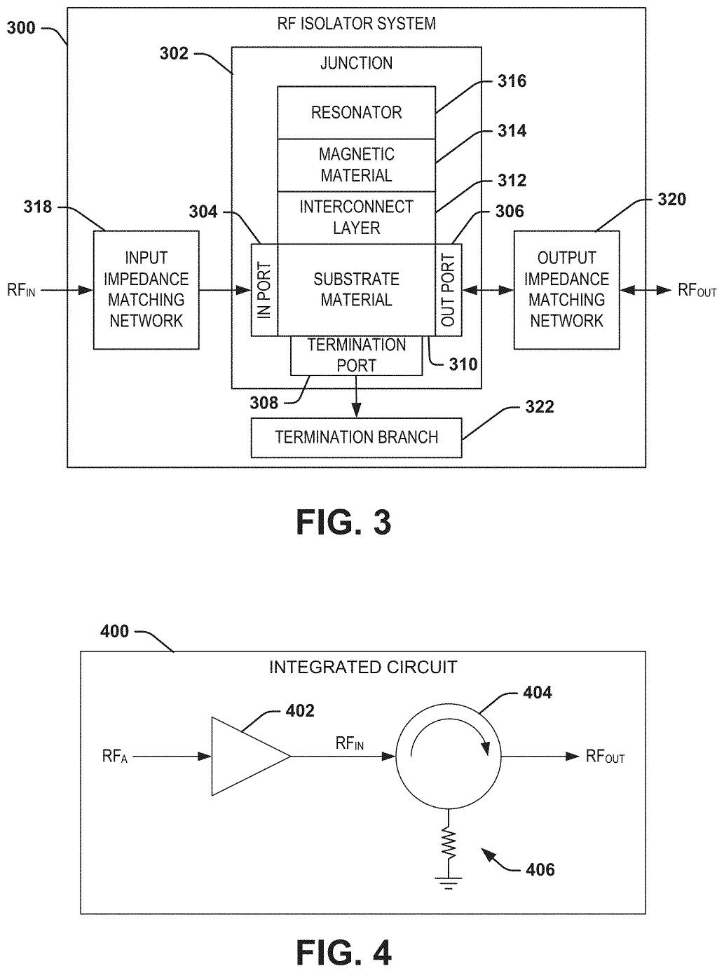

FIG. 3 illustrates an example diagram of an integrated isolator system 300. The integrated isolator system 300 can be configured similarly to the integrated circulator system 100. The integrated isolator system 300 can be implemented in any of a variety of RF signal communication systems to provide unidirectional RF signal propagation.

In the example of FIG. 3, the integrated isolator system 300 includes a junction 302. The junction 302 includes an RF input port 304 (“IN PORT”), an RF output port 306 (“OUT PORT”), and a termination port 308 (“TERMINATION PORT”). As an example, the junction 302 of the integrated isolator system 300 can be configured substantially the same as the junction 200 in the example of FIG. 2. Therefore, in the example of FIG. 3, the junction 302 includes a substrate layer 310, an interconnect layer 312, a magnetic material layer 314, and a resonator 316. The substrate layer 310 can be any of a variety of substrate materials (e.g., GaAs or any of a variety of semiconductor or dielectric materials) on which transmission lines (e.g., microstrip transmission lines) can be patterned to conduct signals (e.g., RF signals). In the example of FIG. 3, the RF input port 304, the RF output port 306, and the termination port 308 are demonstrated as coupled to the substrate layer 310. For example, as described above in the example of FIG. 2 and in greater detail herein, portions of the metal coatings of the substrate layer 310 and the magnetic material layer 314 can correspond to the RF input port 304, the RF output port 306, and the termination port 308. However, the arrangement of the RF input port 304, the RF output port 306, and the termination port 308 is not limited to being fabricated on the substrate layer 310, but can instead be fabricated on the metal coating on the magnetic material layer 314.

Similar to as described above in the example of FIG. 2, the magnetic material layer 314 can overlay the substrate layer 310, such that the interconnect layer 312 can interconnect the substrate layer 310 and the magnetic material layer 314. As an example, the magnetic material layer 314 can be a self-biased ferrite material, such as a hexaferrite material (e.g., barium or strontium), or can be a ferrite material that provides a DC bias in response to an external magnetic field generator (not shown). The resonator 316 can be disposed on an opposite surface of the magnetic material layer 314 relative to the interconnect layer 312. As an example, the magnetic material layer 314 can be formed as a ferrite material slab to provide a DC magnetic field that facilitates the non-reciprocal routing of signals through the resonator 316 from the RF input port 304 to the RF output port 306, and from the RF output port 306 to the termination port 308.

In the example of FIG. 3, the integrated isolator system 300 also includes a first impedance-matching network 318 coupled to the RF input port 304 to receive an RF input signal RF_{IN} and a second impedance-matching network 320 coupled to the RF output port 306 to provide an RF output signal RF_{OUT}. In the example of FIG. 3, the integrated isolator system 300 further includes a termination branch 322 that is coupled to the termination port 308. The termination branch 322 is configured to terminate RF signals that are provided to the RF output port 306 of the junction 302 via the second impedance-matching network 320. For example, the termination branch 322 can include one or more termination circuit components (e.g., resistors and/or active components that interconnect the junction 302 to a low-voltage rail, (e.g., ground). Similar to as described previously, the integrated isolator system 300 can be fabricated in an integrated fabrication process, such that the integrated isolator system 300 can be formed in an integrated circuit with one or more additional circuits that are coupled to the integrated isolator system 300 via microstrip transmission lines to propagate the RF signals RF_{IN} and RF_{OUT}. For example, the integrated isolator system 300 can be fabricated in an integrated manner with the first impedance-matching network 318, the second impedance-matching network 320, and the termination branch 322, as well as the microstrip transmission lines that are coupled to the first impedance-matching network 318 and the second impedance-matching network 320.

As described above, the junction 302 can facilitate the non-reciprocal routing of signals through the resonator 316 from the RF input port 304 to the RF output port 306, and from the RF output port 306 to the termination port 308. Therefore, based on the signal routing characteristics of the junction 302, the integrated isolator system 300 is configured to provide unidirectional propagation of the RF input signal RF_{IN} from the RF input port 304 to the RF output port 306 to provide the RF output signal RF_{OUT} from the RF output port 306. Similarly, the integrated isolator system 300 is configured to provide unidirectional propagation of signals provided at the RF output port 306 to be provided to the termination port 308 to be terminated at the termination branch 322. Therefore, the integrated isolator system 300 can provide unidirectional propagation of signals.

FIG. 4 illustrates an example of an integrated circuit 400. The integrated circuit 400 can be formed on a wafer, and thus packaged in an IC chip, via an integrated circuit fabrication process. The integrated circuit 400 includes a circuit 402, demonstrated as an amplifier in the example of FIG. 4, and an isolator 404. The isolator 404 can correspond to the integrated isolator system 300 in the example of FIG. 3. In the example of FIG. 4, an RF signal RFA is provided to the circuit 402, such that the circuit 402 can propagate (e.g., amplify) the RF signal to provide the RF signal as the RF input signal RF_{IN} to the isolator 404 (e.g., via the first impedance-matching network 318). The isolator 404 can thus provide the RF signal as the RF output signal RF_{OUT} (e.g., via the second impedance-matching network 114). As an example, spurious RF signals that can be provided at the output of the isolator 404 (e.g., via the second impedance-matching network 320) can be provided to the termination branch 406 of the isolator 404, demonstrated in the example of FIG. 4 as a resistor coupled to ground. Therefore, the isolator 404 can protect the circuit 402 from damage or noise resulting from the spurious RF signal provided to the output of the isolator 404.

The circuit 402 is not limited to an amplifier, but can instead be configured as any of a variety of other types of circuits. Additionally, the integrated circuit 400 can include other circuits, such as coupled to the output of the isolator 404. Furthermore, the integrated circuit 400 is not limited to including the isolator 404, but could instead include a circulator as described herein to route signals (e.g., RF signals) between three or more ports in a non-reciprocal manner. Because the integrated circuit 400 can include the circuit 402 and the isolator 404 as integrated together via an integrated circuit fabrication process, the resulting circuit can be implemented in a much more compact manner than typical circulator and/or isolator circuits that are implemented as discrete components. For example, because typical circulators and isolators are implemented as discrete components, signal losses can occur based on soldered and/or mechanical conductive connections between the discrete devices, and the discrete devices can occupy significantly greater physical volume. Accordingly, the integrated circuit 400 that implements the circulator/isolator described herein can be fabricated in a much more compact and inexpensive manner to provide enhanced functionality at a wide range of RF signal frequencies (e.g., from K band to E band).

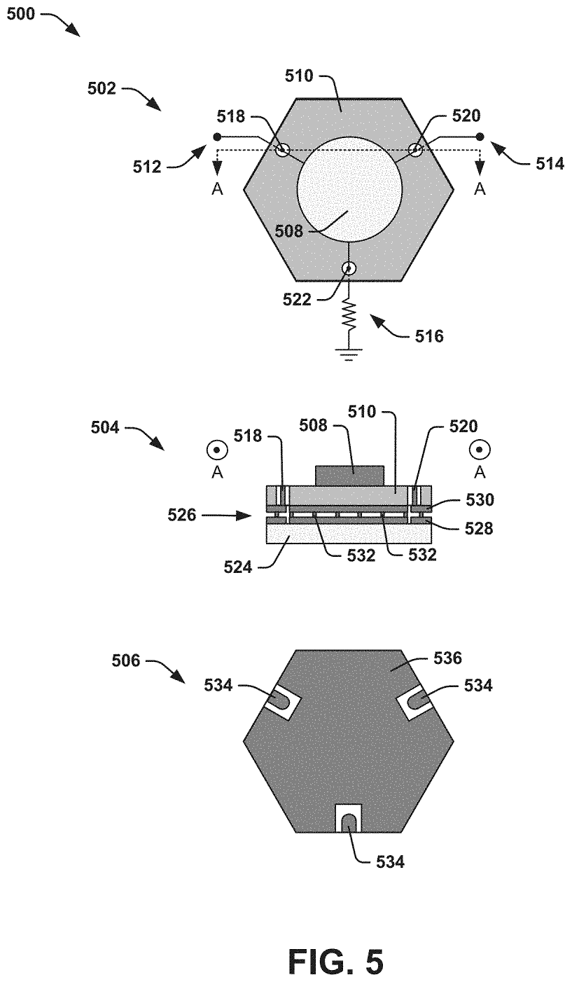

FIG. 5 illustrates an example of an isolator 500. The isolator 500 can correspond to the isolator 300 or the isolator 404 in the respective examples of FIGS. 3 and 4. The isolator 500 is demonstrated in a first view 502, a second view 504, and a third view 506. The first view 502 is demonstrated as an overhead view that includes the resonator 508 and the magnetic material layer 510. The isolator 500 includes an input 512 that can correspond to or can be coupled to the first impedance-matching network 318, an output 514 that can correspond to or can be coupled to the second impedance-matching network 320, and a termination branch 516 that can correspond to the termination branch 322 and which is demonstrated as a grounded resistor. The input 512 is electrically connected to the resonator 508 through a conductive via 518 that extends through the magnetic material layer 510, the output 514 is electrically connected to the resonator 508 through a conductive via 520 that extends through the magnetic material layer 510, and the termination branch 516 is electrically connected to the resonator 508 through a conductive via 522 that extends through the magnetic material layer 510.

The second view 504 is a cross-sectional view taken along the line “A” in the first view 502. The second view 504 demonstrates the resonator 508, the magnetic material layer 510, a substrate layer 524, and an interconnect layer 526 that provides electrical connectivity between the magnetic material layer 510 and the substrate layer 524. The interconnect layer 526 includes a first metal coating 528 that is deposited on a first surface of the substrate layer 524 and a second metal coating 530 that is deposited on a first surface of the magnetic material layer 510 opposite the first surface of the substrate layer 524, and further includes a plurality of interconnect conductors 532 (e.g., solder bumps or metal fusion bonding materials) that provide electrical connectivity between the first metal coating 528 and the second metal coating 530. As a result, in response to precision alignment of magnetic material layer 510 and the substrate layer 524, the interconnect conductors 532 can provide electrical connectivity between the signal portions of the interconnect layer 526 and the ground portions of the interconnect layer 526.

The third view 506 demonstrates a layout of the metal coatings on the first surface of the substrate layer 524 and/or the magnetic material layer 510. As an example, the metal coatings can be any of a variety of conductive metal materials (e.g., gold, silver, copper). As another example, the interconnect conductors 532 can be configured as a solder material, or can be the same material as the respective metal coatings to fuse with the metal coatings. The third view 506 demonstrates metal coating portions 534 that correspond to the signal portions, and are thus coupled to the conductive vias 518, 520, and 522, respectively. Therefore, the metal coating portions 534 on the substrate layer 524 can correspond to the respective first, second, and third ports that are coupled to the respective impedance matching networks and termination branch. The third view also demonstrates a metal coating portion 536 that corresponds to the ground plane. For example, at least one of the interconnect conductors 532 can couple each of the metal coating portions 534 of the substrate layer 524 to a respective one of the metal coating portions 534 of the magnetic material layer 510 (e.g., via a solder bond or material fusion bond) to provide electrical conductivity between the respective sets of metal coating portions 534. As another example, at least one (e.g., an array or pattern) of interconnect conductors can couple the metal coating portion 536 on the substrate layer 524 to the corresponding metal coating portion 536 on the magnetic material layer 510 (e.g., at multiple locations) to provide electrical conductivity between the metal coating portions 536. It is to be understood that the geometry of the metal coating portions 534 and 536 is not limited to as demonstrated in the example of

FIG. 5, and can instead be configured in any of a variety of ways to provide electrical connectivity across the interconnect layer 526.

While the example of FIG. 5 demonstrates an isolator, the same or similar arrangement can be provided for a three-port circulator device, as described above in the examples of FIGS. 1 and 2. As another example, the isolator 500 can be fabricated in an inverted manner, such that the surface upon which the resonator is patterned is facing the surface of the substrate. For inverted fabrication, as an example, instead of the RF signals propagating through the magnetic material along the vias, the vias can provide a ground reference to the top surface of the isolator 500. Alternatively, the isolator 500 could include no vias, and the ground can be provided by wirebonding to an external housing or module. Therefore, the isolator 500 or similarly fabricated circulator can be fabricated in a variety of ways.

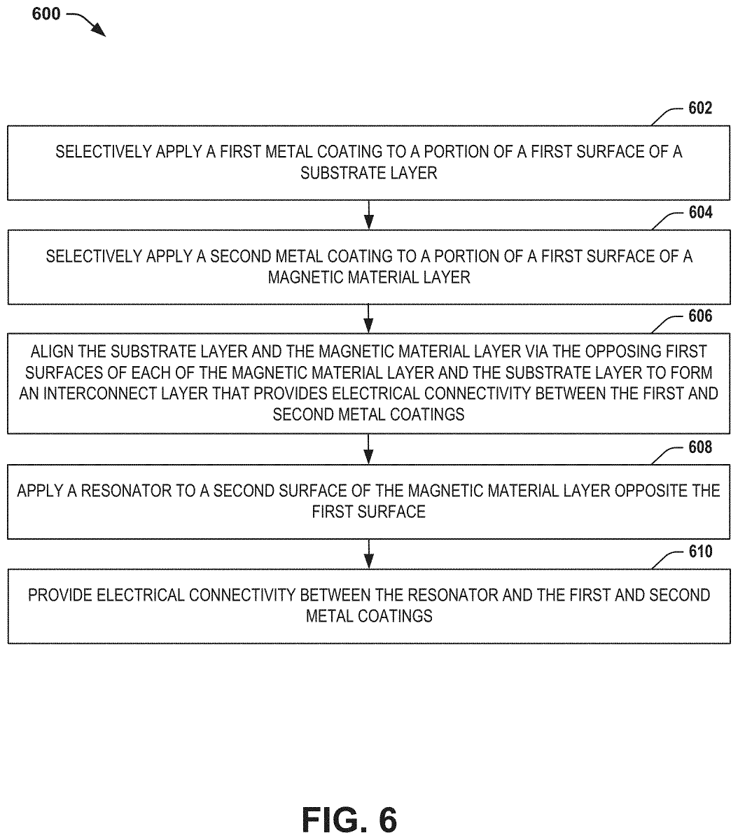

In view of the foregoing structural and functional features described above, a methodology in accordance with various aspects of the present invention will be better appreciated with reference to FIG. 6. While, for purposes of simplicity of explanation, the methodology of FIG. 6 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 6 illustrates an example of a method 600 for fabricating an integrated circulator system (e.g., the circulator system 100). At 602, a first metal coating (e.g., the first metal coating 528) is selectively applied to a portion of a first surface of a substrate layer (e.g., the substrate layer 202). The first metal coating can correspond to signal ports (e.g., the signal ports 104, 106, and 108) associated with the integrated circulator system. At 604, a second metal coating (e.g., the second metal coating 530) is selectively applied to a portion of a first surface of a magnetic material layer (e.g., the magnetic material layer 206). The second metal coating can correspond to the signal ports associated with the integrated circulator system. At 606, the substrate layer and the magnetic material layer are aligned via the opposing first surfaces of each of the magnetic material layer and the substrate layer to form an interconnect layer (e.g., the interconnect layer 204) that provides electrical connectivity between the first and second metal coatings. At 608, a resonator (e.g., the resonator 208) is applied to a second surface of the magnetic material layer opposite the first surface. At 610, electrical connectivity is provided between the resonator and the first and second metal coatings.

What has been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. An integrated circulator system comprising a junction, the junction comprising:
a first port, a second port, and a third port;
a substrate material layer on which the first, second, and third ports are provided;
a magnetic material layer coupled to the substrate layer; and
a resonator coupled to the first, second, and third ports to provide signal transmission from the first port to the second port and from the second port to the third port based on a magnetic field provided by the magnetic material layer.

2. The system of claim 1, wherein the magnetic material layer overlays the substrate layer and the resonator overlays the magnetic material layer, the system further comprising:
a first conductive via extending through the magnetic material layer to interconnect the first port and the resonator;
a second conductive via extending through the magnetic material layer to interconnect the second port and the resonator; and
a third conductive via extending through the magnetic material layer to interconnect the third port and the resonator.

3. The system of claim 1, further comprising an interconnect layer that interconnects the magnetic material layer and the substrate, the interconnect layer comprising:
a first metal coating disposed on a first surface of the substrate layer;
a second metal coating disposed on a first surface of the substrate layer; and
a plurality of conductive interconnect conductors that are disposed between the first metal coating and the second metal coating to provide electrical connectivity between the first metal coating and the second metal coating upon alignment of the magnetic material layer and the substrate layer via the opposing first surfaces of each of the magnetic material layer and the substrate layer.

4. The system of claim 3, wherein each of the first and second metal coatings comprises selective metallization coatings associated with each of the first, second, and third ports, respectively, and a ground plane.

5. The system of claim 4, wherein the plurality of conductive interconnect conductors comprises:
at least one first conductive interconnect conductor configured to provide electrical connectivity between a first portion of each of the first and second metal coatings associated with the first port;
at least one second conductive interconnect conductor configured to provide electrical connectivity between a second portion of each of the first and second metal coatings associated with the second port;
at least one third conductive interconnect conductor configured to provide electrical connectivity between a third portion of each of the first and second metal coatings associated with the third port; and
at least one fourth conductive interconnect conductor configured to provide electrical connectivity between a fourth portion of each of the first and second metal coatings associated with the ground plane.

6. The system of claim 1, further comprising:
a first impedance-matching network that is unitary with the first port, the first impedance-matching network being coupled to a first microstrip transmission line configured to propagate an RF signal to the integrated circulator system; and
a second impedance-matching network that is unitary with the second port, the second impedance-matching network being coupled to a second microstrip transmission line configured to propagate the RF signal from the integrated circulator system.

7. A signal isolator comprising the integrated circulator system of claim 1, the signal isolator comprising at least one termination circuit component coupled to the third port to isolate RF signals that are provided to the signal isolator via the second port.

8. An integrated circuit (IC) chip comprising the integrated circulator system of claim 1, the IC chip further comprising at least one circuit integrated with a first impedance-matching network and a second impedance-matching network.

9. The IC chip of claim 8, wherein the at least one circuit comprises a radio frequency (RF) amplifier circuit integrated with the first impedance-matching network to provide an RF signal to the first impedance-matching network.

10. The IC chip of claim 8, wherein the at least one circuit is electrically coupled to the respective at least one of the respective first and second impedance-matching networks via a microstrip transmission line.

11. A method of fabricating an integrated circulator system, the method comprising:
selectively applying a first metal coating to a portion of a first surface of a substrate layer, the first metal coating corresponding to signal ports associated with the integrated circulator system;
selectively applying a second metal coating to a portion of a first surface of a magnetic material layer, the second metal coating corresponding to the signal ports associated with the integrated circulator system;
aligning the substrate layer and the magnetic material layer via the opposing first surfaces of each of the magnetic material layer and the substrate layer to form an interconnect layer that provides electrical connectivity between the first and second metal coatings;
applying a resonator to a second surface of the magnetic material layer opposite the first surface; and
providing electrical connectivity between the resonator and the first and second metal coatings.

12. The method of claim 11, wherein selectively applying the first metal coating comprises selectively applying a first portion of the first metal coating to the first surface of the substrate layer, wherein selectively applying the second metal coating comprises selectively applying a first portion of the second metal coating to the first surface of the magnetic material layer, wherein the first portion of the first and second metal coatings correspond to the signal ports associated with the integrated circulator system, the method further comprising:
selectively applying a second portion of the first metal coating to the first surface of the substrate layer, the second portion corresponding to a ground plane associated with the integrated circulator system;
selectively applying a second portion of the second metal coating to the first surface of the magnetic material layer, the second portion corresponding to the ground plane associated with the integrated circulator system.

13. The method of claim 12, further comprising applying a plurality of conductive interconnect conductors to the first and second portions of at least one of the first metal coating and the second metal coating, wherein aligning the substrate layer and the magnetic material layer comprises aligning the substrate layer and the magnetic material layer via the opposing first surfaces of each of the magnetic material layer and the substrate layer to provide electrical connectivity between the first portions of the first and second metal coatings via a first portion of the conductive interconnect conductors and electrical connectivity between the second portions of the first and second metal coatings via a second portion of the conductive interconnect conductors.

14. The method of claim 11, wherein providing electrical connectivity between the resonator and the first and second metal coatings comprises providing a plurality of vias that extend from the first and second metal coatings through the magnetic material layer to the resonator.

15. The method of claim 11, further comprising:
fabricating a first impedance-matching network to a first port of the signal ports of the integrated circulator system in an integrated manner; and
fabricating a second impedance-matching network to a second port of the signal ports of the integrated circulator system in the integrated manner.

16. An integrated circuit (IC) comprising an integrated circulator system, the integrated circulator system comprising:
a junction, the junction comprising:
a first port, a second port, and a third port;
a substrate material layer on which the first, second, and third ports are provided;
a magnetic material layer coupled to the substrate layer; and
a resonator coupled to the first, second, and third ports to provide signal transmission from the first port to the second port and from the second port to the third port based on a magnetic field provided by the magnetic material layer;
a first impedance-matching network that is unitary with the first port, the first impedance-matching network being coupled to a first microstrip transmission line configured to propagate an RF signal to the integrated circulator system; and
a second impedance-matching network that is unitary with the second port, the second impedance-matching network being coupled to a second microstrip transmission line configured to propagate the RF signal from the integrated circulator system. The IC of claim 16, wherein the magnetic material layer overlays the substrate layer and the resonator overlays the magnetic material layer, the system further comprising:
a first conductive via extending through the magnetic material layer to interconnect the first port and the resonator;
a second conductive via extending through the magnetic material layer to interconnect the second port and the resonator; and
a third conductive via extending through the magnetic material layer to interconnect the third port and the resonator.

18. The IC of claim 16, further comprising an interconnect layer that interconnects the magnetic material layer and the substrate, the interconnect layer comprising:
a first metal coating disposed on a first surface of the substrate layer;
a second metal coating disposed on a first surface of the substrate layer; and
a plurality of conductive interconnect conductors that are disposed between the first metal coating and the second metal coating to provide electrical connectivity between the first metal coating and the second metal coating upon alignment of the magnetic material layer and the substrate layer via the opposing first surfaces of each of the magnetic material layer and the substrate layer.

19. The IC of claim 18, wherein each of the first and second metal coatings comprises selective metallization coatings associated with each of the first, second, and third ports, respectively, and a ground plane, wherein the plurality of conductive interconnect conductors comprises:
at least one first conductive interconnect conductor configured to provide electrical connectivity between a first portion of each of the first and second metal coatings associated with the first port;
at least one second conductive interconnect conductor configured to provide electrical connectivity between a second portion of each of the first and second metal coatings associated with the second port;
at least one third conductive interconnect conductor configured to provide electrical connectivity between a third portion of each of the first and second metal coatings associated with the third port; and
at least one fourth conductive interconnect conductor configured to provide electrical connectivity between a fourth portion of each of the first and second metal coatings associated with the ground plane.

20. The IC of claim 16, further comprising at least one termination circuit component coupled to the third port to isolate RF signals that are provided to the integrated circulator system via the second port.
